(19) United States
(12) Patent Application Publication
(10) Pub. No.: US 2025/0207256 A1
(43) Pub. Date: Jun. 26, 2025

(54) CHEMICAL VAPOR DEPOSITION APPARATUS

(71) Applicant: IHI BERNEX AG, Olten (CH)

(72) Inventors: Hristo Strakov, Oftringgen (CH); Anja Bäumchen, Suhr (CH); Manfred Pfitzner, Gunzgen (CH); Vasileios Papageorgiou, Reiden (CH)

(21) Appl. No.: 18/851,801

(22) PCT Filed: Feb. 24, 2022
(86) PCT No.: PCT/EP2022/054665

§ 371 Date: Sep. 27, 2024

(51) Int. Cl. C23C 16/455

(52) U.S. Cl. CPC C23C 16/45557

(57) ABSTRACT

The present disclosure relates to a chemical vapor deposition apparatus for providing a surface of a substrate with a layer, the apparatus comprising: a reactor having a chamber for accommodating at least one substrate, a pressure unit configured to generate, in an inner portion of the chamber, a first predetermined pressure. The pressure unit comprises a first pumping stage having at least one liquid ring vacuum pump, and a second pumping stage having at least one dry screw vacuum pump.

### TECHNICAL FIELD

The present disclosure relates to a chemical vapor deposition apparatus for providing a surface of a substrate with a layer.

### BACKGROUND

The term “chemical vapor deposition” (hereinafter: CVD) relates to a provision of layers, especially thin layers, on the surfaces of other materials (substrates), such as workpieces for metal processing (e.g. cutting plates, saw blades, etc.). CVD methods and apparatus commonly rely upon chemical reactions of chemical compounds contained in a process gas, wherein desired main products of the chemical reactions are deposited on the surface of the substrate so as to form a coating or overlay. A known CVD apparatus is described, e.g., in EP 2 304 075 A1.

Known CVD apparatus are commonly tailored to specific applications, such as specific combinations of substrates/coatings. Different applications, in turn, utilize respectively different process parameters. A CVD apparatus tailored to a first application may, however, not be suitable for a second application. There is, hence, a need for promoting flexibility of a CVD apparatus.

Moreover, it has been observed that process gas flow patterns in known CVD apparatus may be spatially unevenly distributed. Such uneven distributions, in turn, may lead to a state in which a first portion of a substrate to be coated is provided with a higher amount and/or concentration of process gas than a second portion of the substrate to be coated. As a consequence, a quality of the coating may be negatively affected. Examples of coatings having reduced quality include coatings having varying thickness and/or coatings having inhomogeneous physical and mechanical properties.

Analogous considerations apply to a pressure curve of the process gas, in particular, to a pressure curve of the processing gas as seen over time. That is, it has been observed that variations of pressure curves of the process gas may negatively affect a quality of the coating.

Likewise, variations of a pressure curve may go along with a slower build-up of a coating. The previously discussed disadvantages may, hence, not only impair a quality of the coating, but may also go along with high costs.

### SUMMARY

It is an objective of the present disclosure to overcome at least one of the above-mentioned disadvantages in a simple but nevertheless effective way.

A chemical vapor deposition apparatus in accordance with the present disclosure is defined in claim 1. Dependent claims relate to embodiments.

A chemical vapor deposition apparatus according to the present disclosure is an apparatus for providing a surface of a substrate with a layer. The apparatus comprises a reactor having a chamber for accommodating at least one substrate and a pressure unit configured to generate, in an inner portion of the chamber, a first predetermined pressure. The pressure unit comprises a first pumping stage having at least one liquid ring vacuum pump, and a second pumping stage having at least one dry screw vacuum pump.

A CVD apparatus as described above may be associated with the technical effect of promoting flexibility and increasing the pressure operation range of the chamber of the reactor down to 0.1 kPa (1 mbar). That is, since the pressure unit comprises a first pumping stage having at least one liquid ring vacuum pump, and a second pumping stage having at least one dry screw vacuum pump, the pressure unit can operate in a widely pressure range with the liquid ring vacuum pump of the first pumping stage having a low delivery capacity and the dry screw vacuum pump of the second pumping stage having a high delivery capacity. By combining a liquid ring vacuum pump with a dry screw vacuum pump, the ability to reliably and finely regulate pressure inside the chamber of the reactor is greatly improved which leads to an increased coating quality. Further, this CVD apparatus may be associated with the technical effect of having a high reliability and an increased robustness. Like other pressure units of CVD Apparatus, the dry screw vacuum pump sucks in the exhaust gas from the reactor, in other words, the dry screw pump is connected to the outlet of the reactor and sucks in the used gas of the CVD process. Due to the bigger gaps between the screws of the dry screw vacuum pump relative to other pump types used for CVD apparatus such as dry roots vacuum pumps and the like, this specific type of pump is less likely to block with by-products contained in the exhaust gas during the CVD process and is therefore less likely to malfunction. The relatively bigger gaps of the dry screw vacuum pump greatly improve the cleaning process which is usually performed using water or water-based solutions and conducted after the CVD process is finished. In this way, any residues of the CVD process that have been deposited in the pump can be removed more efficiently and at the same time more thoroughly, thus improving the lifetime of the pump and reducing costs.

Preferably, a CVD apparatus as described above may be configured to provide a surface of a substrate with a layer without using a plasma. Such plasma would be used for dissociation of the molecules of the process gas. Instead of using plasma for dissociation, the reactor can be heated up to temperatures as high as 1200° C. and thermal energy can be used for dissociation of the molecules of the process gas. Not using a plasma brings the advantages that equipment for generating plasma can be omitted and costs can be reduced and the pressure range required for such CVD apparatus, that use the heat energy as reaction activation energy, can suit very well with the performance of pumping system described in this application.

According to some aspects, the first pumping stage and the second pumping stage of the chemical vapor deposition apparatus are connected in series.

A CVD apparatus as described above may be associated with the technical effect of improving performance. The serial connection of the first pumping stage and the second pumping stage increases the achievable vacuum.

According to some aspects, in the chemical vapor deposition apparatus a suction side of the second pumping stage is connected to the chamber of the reactor and a discharge side of the second pumping stage is connected to a suction side of the first pumping stage.

With this configuration, the vacuum generated in the chamber of the reactor can be further increased, since the dry screw vacuum pump of the second pumping stage has a higher delivery capacity than the liquid ring vacuum pump of the first pumping stage. In this way, both the amount of process gas flowing through the chamber of the reactor and the vacuum can be increased at the same time. This leads to a lower residence time of the chemicals of the process gas in the reactor and an improved distribution of the process gas. Thus, the performance of the CVD apparatus can be further increased. Also, with this configuration, variations of the pressure inside the camber can be reduced and thereby variations in the quality of the coating of the substrates are reduced.

According to some aspects the first pumping stage has a first liquid ring vacuum pump and a second liquid ring vacuum pump connected in parallel.

With the first pumping stage having two liquid ring vacuum pumps being connected in parallel, the dimensions of the type of liquid ring vacuum pump used in the first pumping stage can be reduced. This is, because the delivery capacity of the first and second liquid ring vacuum m pumps connected in parallel add up. Thus, smaller pumps with less power can be used, the costs of the first pumping stage can be reduced and the installation space of the CVD apparatus can be used more flexibly.

According to some aspects, the apparatus further comprises a pressure regulation unit configured to control the first predetermined pressure generated by the pressure unit. The first predetermined pressure is adjustable in the entire range covering 0.1 kPa (1 mbar) to 90 kPa (900 mbar).

A CVD apparatus as described above may be associated with the technical effect of improving flexibility and reliability on the coating quality. With the pressure unit configured to generate, in an inner portion of the chamber, a pressure that is adjustable in the entire range covering 0.1 kPa (1 mbar) to 90 kPa (900 mbar) and the pressure regulation unit configured to control this pressure, the CVD apparatus may be used, e.g., for coating processes relying upon pressures between 0.1 kPa (1 mbar) to 40 kPa (400 mbar), and also for coating processes relying upon pressures between 40 kPa (400 mbar) to 90 kPa (900 mbar). The extend of the generated vacuum and the absence of variations thereof have great positive influence on the coating quality.

According to some aspects, the pressure regulation unit is configured to control the first predetermined pressure by at least varying the rotational speed of the dry screw pump.

As outlined in the introductory portion of the present application, variations of a pressure curves of the process gas may negatively affect a quality of the coating. Moreover, variations of a pressure curve may go along with a slower build-up of a coating. The vacuum generated by the dry screw pump depends on its rotational speed. With a pressure regulation unit which is configured to vary the rotational speed of the dry screw pump, the pressure generated in the chamber of the reactor can be adjusted in fine steps and maintained with comparatively small variations.

According to some aspects, the chemical vapor deposition apparatus further comprises at least one valve configured to reduce the intersection of at least one connection to the chamber, wherein optionally, an opening degree of the valve is controlled by the pressure regulation unit.

It has turned out that utilizing in a CVD apparatus a pressure unit comprising a first pumping stage having a liquid ring vacuum pump and a second pumping stage having a dry screw pump may go along with a rather stable pressure curve (i.e., a pressure curve having variations of a rather low amplitude) and extending the operation pressure range down to 0.1 kPa (1 mbar). However, especially at a pressure as low as 0.1 kPa, the vacuum generated inside the chamber of the reactor may still be subject to certain pressure variations. A CVD apparatus as described above allows a precise control of the pressure inside the chamber by means of the at least one valve, that is preferably a throttle valve, configured to reduce the intersection of one connection from the dry screw vacuum pump to the chamber, preferably the outlet of the chamber. Also, variations in pressure inside the chamber of the reactor can be further reduced or completely eliminated. Furthermore, the pressure inside the chamber can be controlled even more precise by controlling both the at least one valve and the rotational speed of at least one pump. With these measures, the coating quality, that is, the homogeneity and the thickness of the coating can be adjusted precisely.

According to some aspects, the chemical vapor deposition apparatus further comprises a second valve configured to reduce the intersection of at least one connection to the chamber. The second valve has a size which is different to that of the at least one valve and is connected in parallel to the at least one valve. An opening degree of the second valve and the opening degree of the at least one valve are controlled by the pressure regulation unit at the same time.

With the use of two valves connected in parallel and of different sizes, which means that the valves have different intersections and are designed for different mass flow rates, the variations in the pressure generated in the chamber can be suppressed even more effectively. This is because the pressure regulation unit may control these valves with different control strategies. For example, with controlling the opening degree of the bigger valve, greater variations in the generated pressure can be compensated or eliminated and with controlling the opening degree of the smaller valve, finer variations in the generated pressure can be controlled. According to some aspects, the at least one dry screw vacuum pump has a liquid cooling system configured to transfer heat between a liquid and the at least one dry screw vacuum pump.

Compared to the CVD apparatus known from the state of the art, with this configuration using a dry screw vacuum pump in conjunction with a liquid cooling system, the CVD process can be maintained substantially longer without the dry screw vacuum pump overheating Especially, when Nitrogen (N₂) and/or Argon (Ar) are used as carrier gas or when using a high gas flow rate of Hydrogen (H₂), a pump of a second pumping stage often needs to be operated with high rotational speeds causing the pump of the second pumping stage to heat up. If the pump is operated for a certain time under these conditions, the pump tends to overheat when the heat inside the pump cannot be sufficiently dissipated. This effect occurs in particular with dry roots vacuum pumps. According to the present invention, this negative effect can efficiently be avoided when combining a dry screw vacuum pump which has relatively bigger gaps between the screws and a liquid cooling system.

### BRIEF DESCRIPTION OF THE DRAWINGS

Additional advantages and features of the present disclosure, that can be realized on their own or in combination with one or several features discussed above, insofar as the features do not interfere with each other, will become apparent from the following description of working examples and/or optional aspects and/or embodiments. The description is provided with reference to the accompanying drawings, in which:

FIG. 1a is a schematic view showing the pressure unit 6 comprising a single-stage pumping system with one single liquid ring vacuum pump 601 and being connected to a reactor 1.

FIG. 1b is a schematic view showing the pressure unit 6 comprising a single-stage pumping system with two liquid ring vacuum pumps 601 connected in parallel and being connected to a reactor 1.

FIG. 2 is a schematic view showing the pressure unit 6 having a first pumping stage 60, a second pumping stage 61 and a third pumping stage 62; the first pumping stage comprising two liquid ring vacuum pumps 601 connected in parallel, the second pumping stage 61 comprising a dry roots vacuum pump 612 and the third pumping stage 62 comprising a second dry roots vacuum pump; the two dry roots vacuum pumps 612 of the second and the third pumping stage being connected in series, the pressure unit 6 being connected to a reactor 1.

FIG. 3 is a schematic view showing the pressure unit 6 having first pumping stage 60 and a second pumping stage 61, the first pumping stage comprising two liquid ring vacuum pumps 601 connected in parallel, the second pumping stage 61 comprising one dry screw vacuum pump 611, the first and second pumping stage being connected in series and the pressure unit 6 being connected to a reactor 1.

FIG. 4 is a chart illustrating the pressure inside the chamber of the reactor in mbar generated by a pressure unit of an exemplary configuration and that of a preferred embodiment as a function of the mass flow of Hydrogen (H2) in norm liter per minute (Nl/min).

### DETAILED DESCRIPTION OF PREFERRED EMBODIMENTS

Embodiments of devices, uses and methods in accordance with the present disclosure will hereinafter be explained in detail, by way of non-limiting example only, and with reference to the accompanying drawings. Like reference signs appearing in different figures denote identical, corresponding, or functionally similar elements, unless indicated otherwise.

The pressure unit 6 is configured to generate, in an inner portion of the chamber 10, a first predetermined pressure, the first predetermined pressure being adjustable in the entire range covering 0.1 kPa (1 mbar) to 90 kPa (900 mbar).

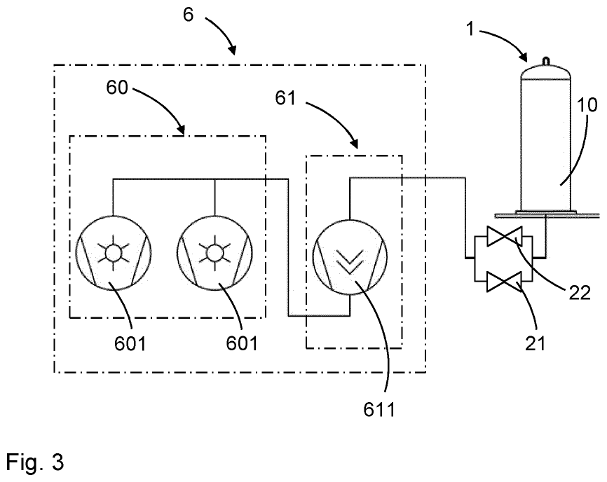

As schematically shown in FIG. 3, the pressure unit 6 comprises a liquid ring vacuum pump 60. The use of a liquid ring vacuum pump is associated with the technical effect that a liquid is used to create a vacuum. When using a solution of NaOH in such a pump, the exhaust gas can already be cleaned respectively neutralized inside the pump. This also promotes the lifetime of the pump and reduces corrosion as the acid exhaust gases get at least partially neutralized. Further, the liquid inside the liquid ring vacuum pump 60 washes away residuals of the acid exhaust gas inside the pump.

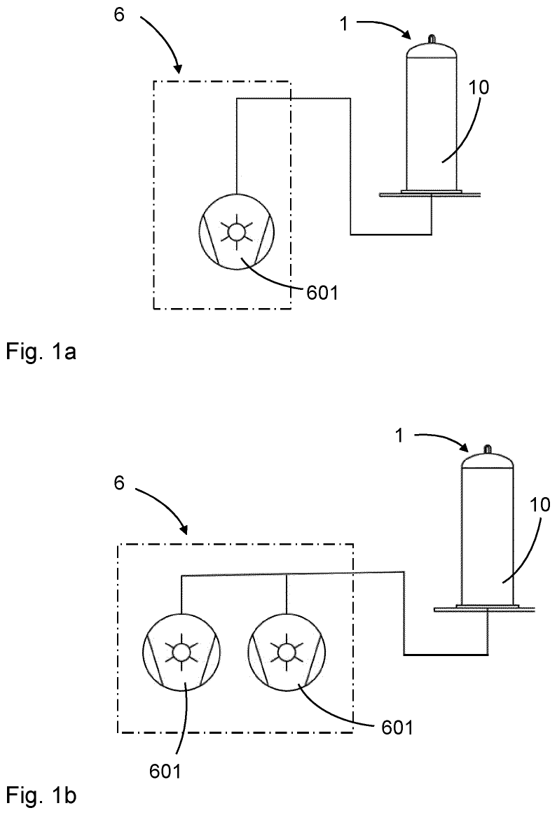

Providing two liquid ring vacuum pumps 601 connected in parallel as shown in FIG. 3 is associated with the technical effect of promoting efficiency of the CVD apparatus. When the chemical vapor deposition process is operated with higher gas flows and/or a greater vacuum is required, the second liquid ring vacuum pump 601 is used in addition to the first one. In this way, the first and second liquid ring vacuum pump 601 can each be of smaller dimension. When the process is operated with lower gas flows and/or less vacuum is required, one of the liquid ring vacuum pumps 601 can be switched off again. In this manner, the CVD apparatus can be operated more economically as it would be the case when only one big liquid ring vacuum pump 601 is provided. Likewise, the demand of required resources for running the pumps such as liquid solution (NaOH), power consumption etc. can be reduced. Such pressure unit 6 is typically associated with generating pressures as low as 5 kPa (50 mbar). Known CVD apparatus have single-stage pressure units 6 with one or two liquid ring vacuum pumps 601 as shown in FIGS. 1a and 1b.

According to the present disclosure, the pressure unit 6, however, comprises a first pumping stage and a second pumping stage. Each pumping stage can comprise one or more pumps.

It is preferred that the second pumping stage 61 of the pressure unit 6 comprises a dry screw vacuum pump. The second pumping stage 61 is preferably connected to the first pumping stage 60 in series as shown in FIG. 3.

When in the second pumping stage a dry roots vacuum pump is used, the pump often tends to overheat. This is due to the fact that when using Nitrogen (N₂) and/or Argon (Ar) as a carrier gas or when using high gas flow rates of Hydrogen (H₂), the pump of the second pumping stage often needs to be operated with high rotational speeds. Due to the relatively smaller gaps between the rotating parts, e.g. the screws, the dry roots vacuum pump generates a lot of heat during operation, resulting in a relatively quick overheat of the dry roots vacuum pump. If the pump overheats, the CVD process needs to be paused to avoid any damage on the pump.

In this regard, using a dry screw vacuum pump in the second pumping stage has turned out to be advantageous. When used in the second pumping stage, the dry screw vacuum pump is less likely to overheat. Presumably due to the relatively bigger gaps between the rotating parts, e.g. the screws, the dry screw vacuum pump generates less heat during operation. This minimizes the risk that the CVD process will have to be stopped to prevent damage at the pump and thus, productivity can be increased. This effect can be significantly enhanced by providing a liquid cooling system for the dry screw vacuum pump as this allows the heat generated to be dissipated more effectively.

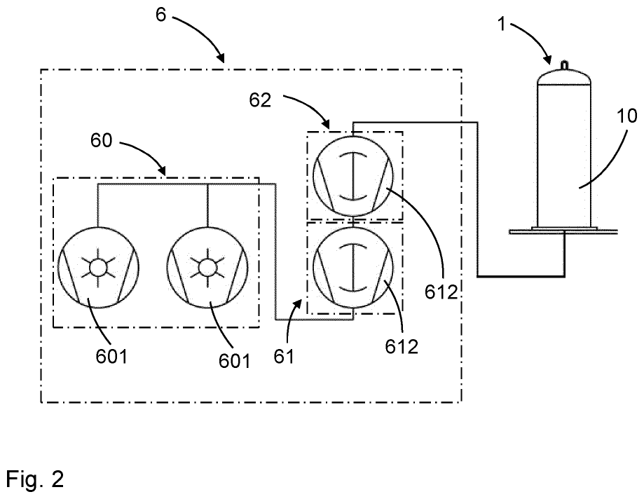

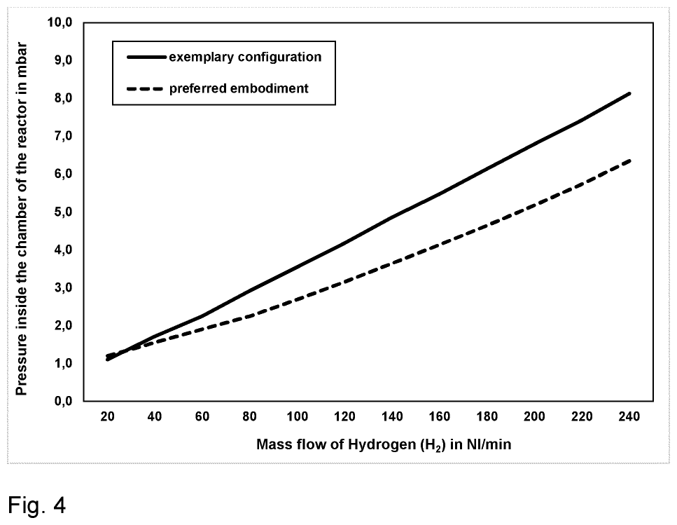

As is can be seen from the Graph of the preferred embodiment in FIG. 4, when using a dry screw vacuum pump 611 in the second pumping stage 61 and Hydrogen (H₂) as a carrier gas, it is difficult to operate the CVD process with carrier gas flow rates of below 30 norm liters per minute (Nl/m). This is due to the bigger gaps between the rotating screws compared to, for example, a dry roots vacuum pump 610. At the same time however, surprisingly, the use of a dry screw vacuum pump 611 in the second pumping stage 61 of the pressure unit 6 leads to various advantageous effects. In contrast to the use of, for example, a dry roots vacuum pump 610 in the second pumping stage 61, the use of a dry screw vacuum pump 611 benefits from the higher compression factor of the dry screw vacuum pump 611 which improves the delivery capacity of the pressure unit 6. Therefore, the slightly lower performance of providing a vacuum inside the chamber at very low gas flow rates, in comparison to an exemplary configuration discussed below, is negligible and the system is perfectly suited to work at high gas flow rates and to achieve a great vacuum. This results in lower residence time of the chemicals of the process gas in the reactor and an improved distribution of the process gas, as outlined further above. Thus, it is possible to reduce the number of pumping stages in the pressure unit 6 or the pumps used in each stage, thereby reducing costs. If instead of the dry screw vacuum pump 611, a dry roots vacuum pump 610 is used in the second pumping stage 61, another dry roots vacuum pump 610 connected in series forming a third pumping stage 62 will usually be needed due to the lower compression factor of the dry roots vacuum pump 610. Such configuration is shown in FIG. 2. Hence, with the use of a dry screw vacuum pump 611, the design of the pressure unit 6 can be simplified. In contrast to, for example, a dry roots vacuum pump 610, a dry screw vacuum pump 611 has bigger gaps between the rotating parts, e.g. the screws. Therefore, when used in a CVD apparatus, the dry screw vacuum pump 611 is less prone to clogging or blocking with by-products of the CVD process. Thus, the reliability of the CVD apparatus can be improved. Additionally, due to the bigger gaps compared to a dry roots pump, the process of cleaning the pump for example with water after the CVD process is finished can be improved. The pump can be cleaned easier and more thoroughly.

Norm liter (Nl), sometimes also referenced to as standard liter, is a commonly used volume unit used to compare gas quantities present at different pressures and temperatures. A norm liter as used in this description refers to the volume of a gas at standard conditions, namely at standard pressure of 101 325 Pa and at a standard temperature of 0° C.

In the preferred embodiment, the pressure unit 6 comprises a first pumping stage 60 and a second pumping stage 61, the first pumping stage 60 having one liquid ring vacuum pump 601 and the second pumping stage 61 having one dry screw vacuum pump 611. While the liquid ring vacuum pump 601 of the first pumping stage 60 may have a relatively low specified delivery capacity of about 250 to 650 m³/h (cubic meters per hour), the dry screw vacuum pump 611 of the second pumping stage 61 may have a relatively high specified delivery capacity of about 8000 m³/h.

An exemplary pressure unit 6, in which a dry roots vacuum pump 610 is used instead of the dry screw vacuum pump 611, comprises a first pumping stage 60, a second pumping stage 61 and a third pumping stage 62, the pumping stages being connected in series. The first pumping stage 60 having two liquid ring vacuum pumps 601 connected in parallel, the second pumping stage 61 having one dry roots vacuum pump 610 and the third pumping stage having a second dry roots vacuum pump 610. Such configuration is shown in FIG. 2. Since the first pumping stage 60 has two liquid ring vacuum pumps 601, the first pumping stage 60 may have a specified delivery capacity of about 250 to 650 m³/h. The second pumping stage 61 having one dry roots vacuum pump may have a specified delivery capacity of about 1000 to 2000 m³/h. The third pumping stage 62 having one dry roots vacuum pump may have a specified delivery capacity of about 2000 to 6000 m³/h. The delivery capacities refer to delivery capacities specified by the pump manufacturers.

Besides the advantageous effects described above, also in terms of performance, the pressure unit 6 of the preferred embodiment with just two pumping stages and using a dry screw pump 611 has proven to be advantageous over the exemplary configuration with two dry root pumps 610 described above. As it becomes apparent from the graph in FIG. 4, while maintaining the same pressure inside the chamber 10 of the reactor 1, the pressure unit 6 of the preferred embodiment delivers a higher flow rate of Hydrogen (H₂) (at standard conditions in norm liter per minute (Nl/min)) than the pressure unit 6 of the exemplary configuration above a pressure as low as about 0.14 kPa (1.4 mbar). In other words, when delivering the same mass flow of Hydrogen of 30 Nl/min or more, the pressure unit 6 of the preferred embodiment is capable of creating a greater vacuum in the chamber 10 of the reactor 1 than the pressure unit 6 of the exemplary configuration. It is to be noted that the marginal areas of the graph in FIG. 4 represent the end of the measurements and not necessarily the performance limits of the pressure unit.

The pressure generated by the pressure unit 6 can be controlled by a pressure regulation unit. For controlling the generated pressure, the pressure regulation unit may vary the rotational speed of the pumps of the respective pumping stage. For such control, each pump may be operated with frequency converters. The control of the rotational speed, for example via frequency control, of the dry screw vacuum pump 611 allows particularly precise control of the generated pressure. Further, the pressure inside the chamber 10 can be controlled by controlling the opening degree of at least one valve provided in a connection to the chamber 10. The connection to the chamber 10 is preferably a gas outlet of the chamber 10.

While various example embodiments of devices, methods and/or uses in accordance with the present disclosure have been described above, it should be understood that they have been presented by way of example, and not limitation. It will be apparent to persons skilled in the relevant art(s) that various changes in form and detail can be made therein. Thus, the present disclosure should not be limited by any of the above described example embodiments but should be defined only in accordance with the following claims and their equivalents.

Further, it is to be understood that certain features described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

1. A chemical vapor deposition apparatus for providing a surface of a substrate with a layer, the apparatus comprising:
a reactor (1) having a chamber (10) for accommodating at least one substrate;
a pressure unit (6) configured to generate, in an inner portion of the chamber (10), a first predetermined pressure, characterized in that the pressure unit comprises:
a first pumping stage (60) having at least one liquid ring vacuum pump (601), and
a second pumping stage (61) having at least one dry screw vacuum pump (611).

2. The chemical vapor deposition apparatus of claim 1, characterized in that the first pumping stage (60) and the second pumping stage (61) are connected in series.

3. The chemical vapor deposition apparatus of claim 2, characterized in that a suction side of the second pumping stage (61) is connected to the chamber (10) of the reactor (1) and a discharge side of the second pumping stage (61) is connected to a suction side of the first pumping stage (60).

4. The chemical vapor deposition apparatus of any one of the preceding claims, characterized in that the first pumping stage (60) has a first liquid ring vacuum pump (601) and a second liquid ring vacuum pump (601) connected in parallel.

5. The chemical vapor deposition apparatus of any one of the preceding claims, characterized in that the apparatus further comprises:
a pressure regulation unit configured to control the first predetermined pressure generated by the pressure unit (6),
wherein the first predetermined pressure is adjustable in the entire range covering 0.1 kPa (1 mbar) to 90 kPa (900 mbar).

6. The chemical vapor deposition apparatus of claim 5, characterized in that the pressure regulation unit is configured to control the first predetermined pressure by at least varying the rotational speed of the dry screw pump.

7. The chemical vapor deposition apparatus of claim 5 or 6, characterized in that the apparatus further comprises:
at least one valve configured to reduce the intersection of at least one connection to the chamber (10); wherein optionally,
an opening degree of the valve is controlled by the pressure regulation unit.

8. The chemical vapor deposition apparatus of claim 7, characterized in that the apparatus further comprises:
a second valve configured to reduce the intersection of at least one connection to the chamber (10), wherein
the second valve has a size different to that of the at least one valve and is connected in parallel to the at least one valve, and
an opening degree of the second valve and the opening degree of the at least one valve are controlled by the pressure regulation unit.

9. The chemical vapor deposition apparatus of any one of the preceding claims, characterized in that, the one dry screw vacuum pump (611) has a liquid cooling system configured to transfer heat between a liquid and the at least one dry screw vacuum pump (611).
